(19) United States
(12) Patent Application Publication
(10) Pub. No.: US 2019/0214565 A1
(43) Pub. Date: Jul. 11, 2019

(54) DEPOSITION OF CARBON NANOTUBES ON SUBSTRATES AND ELECTRICAL DEVICES MANUFACTURED THEREFROM

(71) Applicant: Carbonics Inc., Culver City, CA (US)

(72) Inventors: Tyler Andrew Cain, Culver City, CA (US); Alexander Allen Kane, Culver City, CA (US); Christopher Michael Rutherglen, Culver City, CA (US); Kosmas Galatsis, Culver City, CA (US); Philbert Francis Marsh, Culver City, CA (US)

(21) Appl. No.: 16/199,915

(22) Filed: Nov. 26, 2018

Related U.S. Application Data
(60) Provisional application No. 62/615,613, filed on Jan. 10, 2018.

(51) Int. Cl. H01L 51/00; H01L 51/05; H01L 51/10

(52) U.S. Cl. CPC H01L 51/0012; H01L 51/0003; H01L 51/105; H01L 51/0545; H01L 51/0558; H01L 51/0048

(57) ABSTRACT

Manufacturing an electrical device including providing a substrate having a surface and providing a sacrificial layer on the surface of the substrate. Depositing a solution of carbon nanotubes suspended in a solvent on a surface of the sacrificial layer and removing the solvent of the solution to thereby leave the carbon nanotubes on the sacrificial layer. Removing the sacrificial layer whereby the carbon nanotubes form a carbon nanotube layer and the carbon nanotubes in the carbon nanotube layer are aligned with each other. An electrical device, including a substrate having a surface and a layer of carbon nanotubes on the surface of the substrate. The carbon nanotubes in the layer are aligned with each other, such that an alignment angle between adjacent ones of the carbon nanotubes is within about ±20 degrees.

### CROSS-REFERENCE TO RELATED APPLICATION

This application claims the benefit of U.S. Provisional Application Ser. No. 62/615,613, filed by Tyler Andrew Cain on Jan. 10, 2018, entitled “DEPOSITION OF CARBON NANOTUBES ON SUBSTRATES AND ELECTRICAL DEVICES MANUFACTURED THEREFROM,” commonly assigned with this application and incorporated herein by reference.

### TECHNICAL FIELD

This application is directed, in general, to electrical devices including carbon nanotubes, and methods of depositing carbon nanotubes onto a substrate of the electrical device.

### BACKGROUND

The deposition of carbon nanotubes (CNTs) onto substrates of electrical devices is an important step in the manufacture of such devices. In particular, depositing CNTs such that they are self-aligned with each other, and such that the aligned CNTs form a direct path between contacts of the device, are important to achieving efficient electron transport. However, existing deposition processes, such as floating evaporative self-assembly (FESA) processes, which to our knowledge have only been shown to be effective at providing self-aligned CNTs if the CNTs are deposited on a uniform silicon dioxide (SiO₂) substrate surface. In an effort to expand the range of material surfaces that CNTs can be deposited on, the surface may be pretreated with hydrophobic agents, such as hexamethyldisilazne (HMDS). However, such coatings may not be compatible with non-SiO₂ surfaces or not provide the desired range of wettability conducive to the deposition of CNTs.

### SUMMARY

One aspect provides a method of manufacturing an electrical device. The method includes providing a substrate having a surface and providing a sacrificial layer on the surface of the substrate. The method also includes depositing a solution of carbon nanotubes suspended in a solvent on a surface of the sacrificial layer and removing the solvent of the solution to thereby leave the carbon nanotubes on the sacrificial layer. The method further includes removing the sacrificial layer whereby the carbon nanotubes form a carbon nanotube layer and the carbon nanotubes in the carbon nanotube layer are aligned with each other.

In any such embodiments, the substrate can include a base layer and a thin film layer on the base layer, the thin film layer providing the substrate surface, the substrate surface substantially free of silicon oxide. In some such embodiments In any such embodiments the sacrificial layer can be composed of silicon oxide having a formula of SiOx, wherein x equals from about 1.5 to 2.5. In any such embodiments, the solution of carbon nanotubes can form a contact angle on the surface of the sacrificial layer that is in the range of about 5 to about 90 degrees. In some such embodiments, the carbon nanotubes can be single-walled carbon nanotubes, double-walled carbon nanotubes, semiconducting single-walled carbon nanotubes, or single-walled carbon nanotubes wrapped in a polymer, and the solvent includes chloroform or chloroform plus one or more alcohols in quantities miscible with chloroform.

In any such embodiments, removing the sacrificial layer includes one of etching the sacrificial layer via wet etching or vapor etching. In some such embodiments, removing the sacrificial layer by vapor etching can include placing the substrate with the sacrificial layer and the solution of carbon nanotubes thereon into a chamber, adjusting the temperature of the substrate to a temperature in a range from 10° C. to 100° C. and introducing a HF vapor etchant into the chamber to expose the surface of the sacrificial layer to etch the sacrificial layer.

Any such embodiments of the method can further include depositing a hydrophobic agent on the surface of the sacrificial layer to form a hydrophobic layer on the sacrificial layer and then, depositing the solution of carbon nanotubes suspended in the solvent on the surface of the sacrificial layer and on a surface of the hydrophobic layer and then, as part of removing the sacrificial layer, removing the hydrophobic layer. In some such embodiments, the solution of carbon nanotubes can form a contact angle on the surface of the hydrophobic layer that is in the range of about 5 to about 90 degrees.

In any such embodiments, the carbon nanotubes of the carbon nanotube layer can have a packing density of at least about 40 carbon nanotubes per micron of dimension perpendicular to long axis lengths of the aligned carbon nanotubes. In any such embodiments, the carbon nanotubes aligned with each other in the carbon nanotube layer can have an alignment angle between adjacent ones of the carbon nanotubes is within about ±20 degrees.

Another aspect is an electrical device, the electrical device including a substrate having a surface and a layer of carbon nanotubes on the surface of the substrate, wherein the carbon nanotubes in the layer are aligned with each other, such that an alignment angle between adjacent ones of the carbon nanotubes is within about ±20 degrees.

In any such embodiments, the carbon nanotubes of the carbon nanotube layer can have a packing density of at least about 40 carbon nanotubes per micron of dimension perpendicular to long axis lengths of the carbon nanotubes. In any such embodiments, the substrate surface can be substantially free of silicon oxide. In any such embodiments, the substrate can include a thin film layer providing the substrate surface, the thin film layer composed of: silicon nitride, Al₂O₃, HfO₂, TiO₂, ZrO₂, AlN, diamond, spin-on-glass, or benzocyclobutene polymer. In any such embodiments,

In any such embodiments, the electrical device can be configured as a back-gate field effect transistor and further includes a source electrode and a drain electrode located on the substrate surface. One end of the carbon nanotube layer can contact the source electrode and an opposite end of the carbon nanotube layer can contact the drain electrode. In some such embodiments, the source electrode and the drain electrode can be elevated above the substrate surface and the carbon nanotube layer can be suspended above the substrate surface such that not more than about 50 percent of a length of the layer of carbon nanotubes does not directly physically contact the substrate surface. In some such embodiments, the carbon nanotube layer can suspended above the substrate surface such that none of the layer of carbon nanotubes directly physically contacts the substrate surface. In any such embodiments, the field effect transistor further can include a metal gate electrode buried in the substrate, the metal gate electrode configured to generate an electric field capable of altering the resistivity of the CNT layer.

### BRIEF DESCRIPTION

Reference is now made to the following descriptions taken in conjunction with the accompanying drawings, in which:

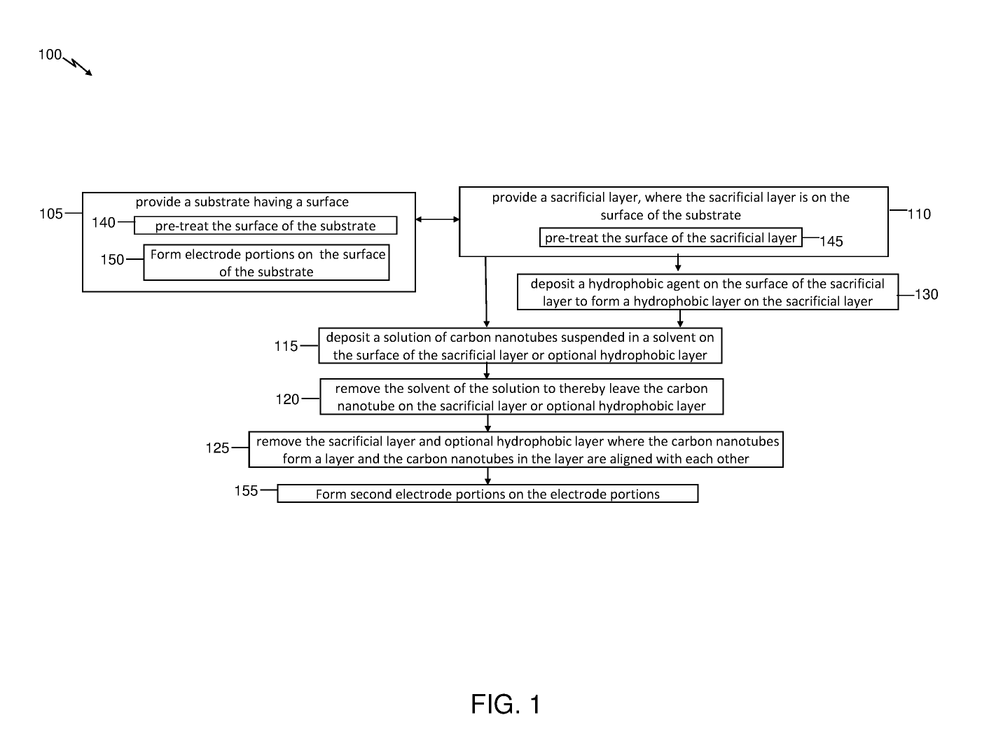

FIG. 1 presents a flow diagram of an example method of manufacturing an electrical device in accordance with the disclosure;

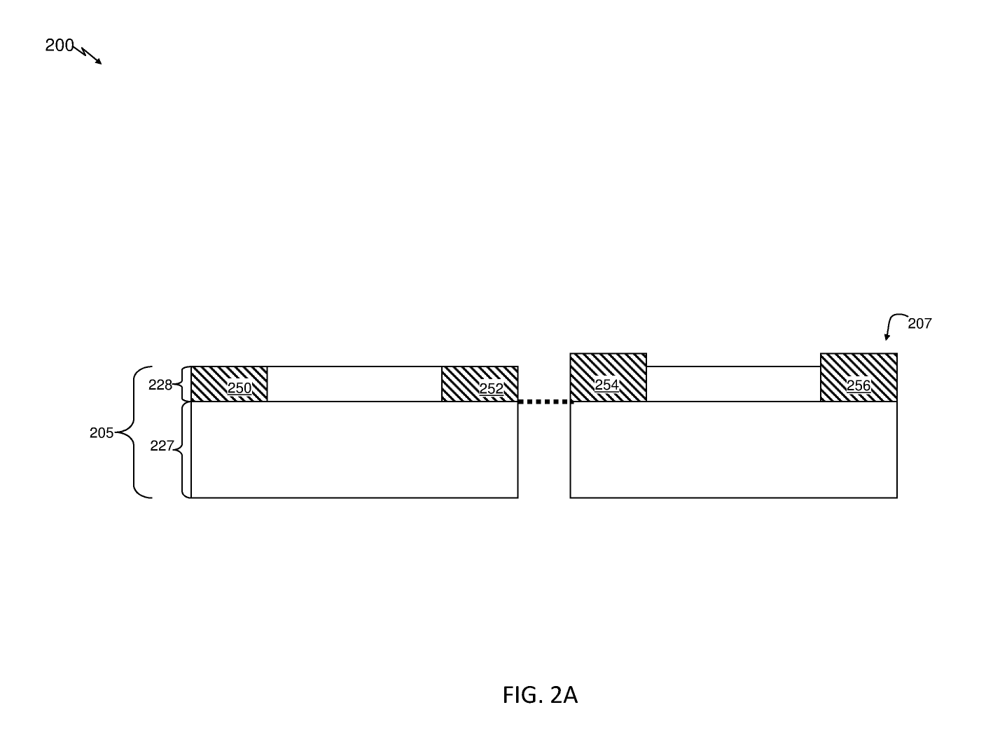

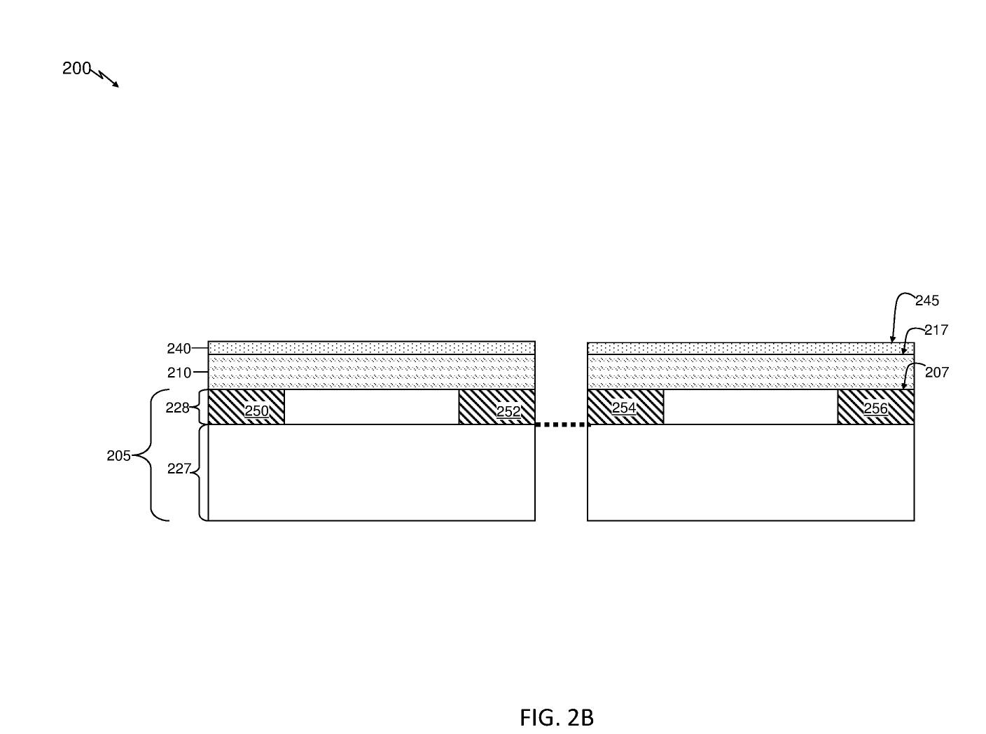

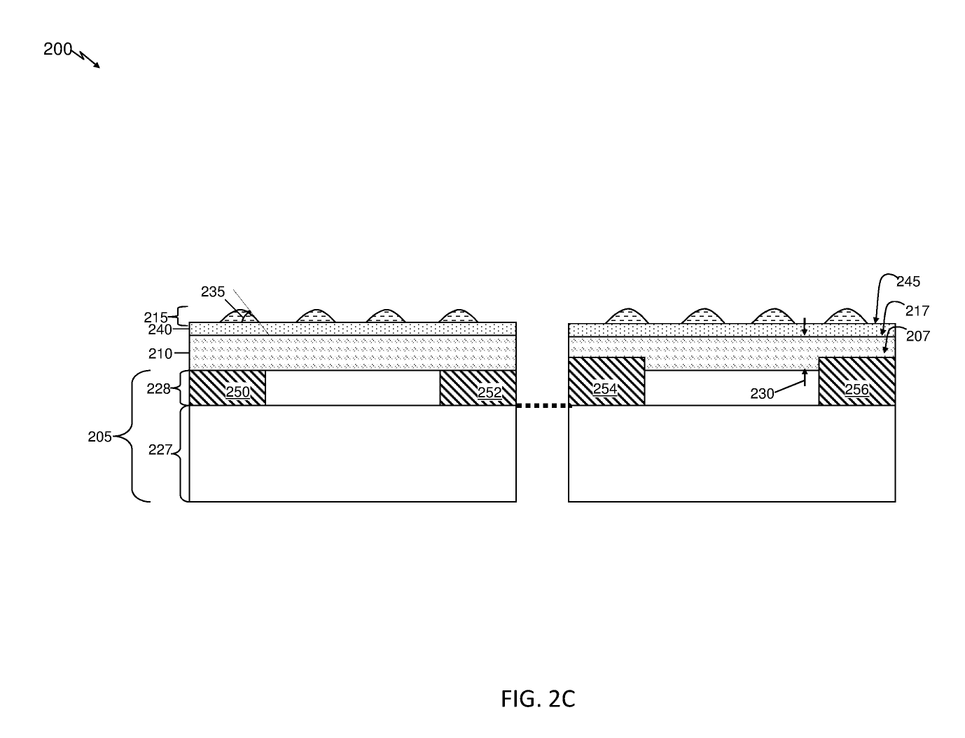

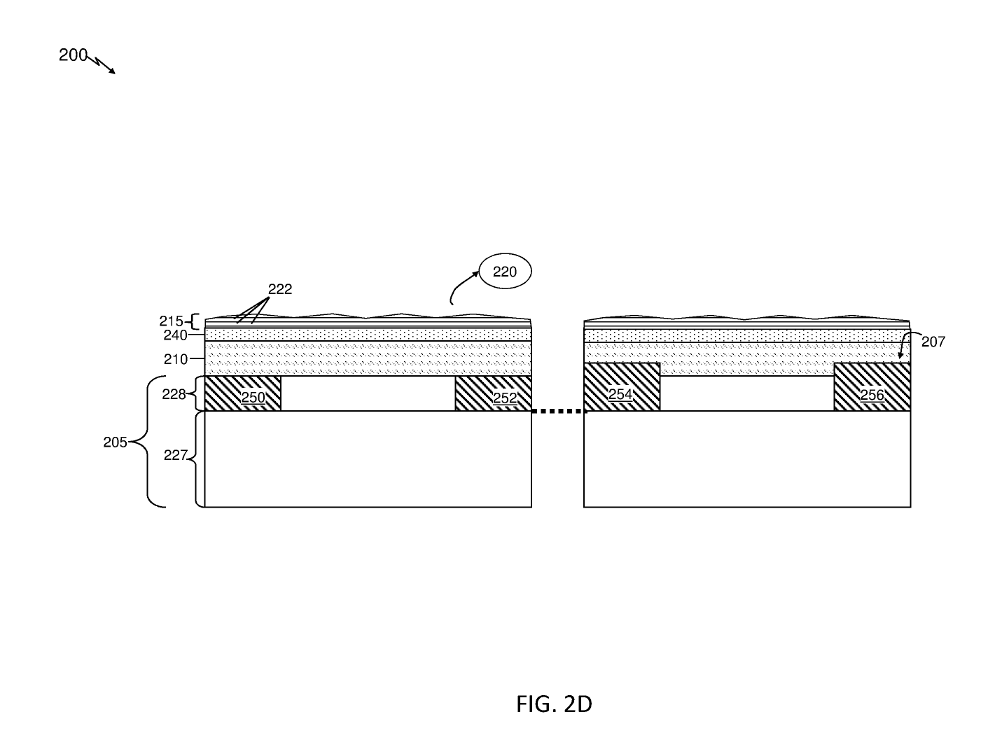

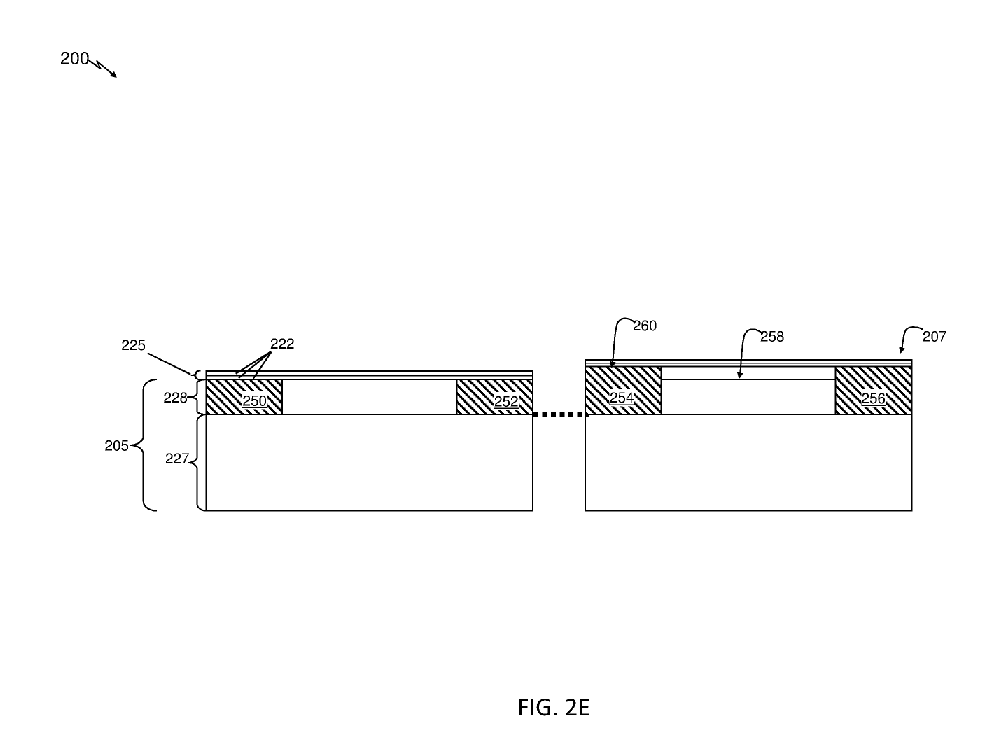

FIGS. 2A to 2E present cross-sectional views of an example electrical device at different stages of manufacture, such as different stages in the example method disclosed in the context of FIG. 1;

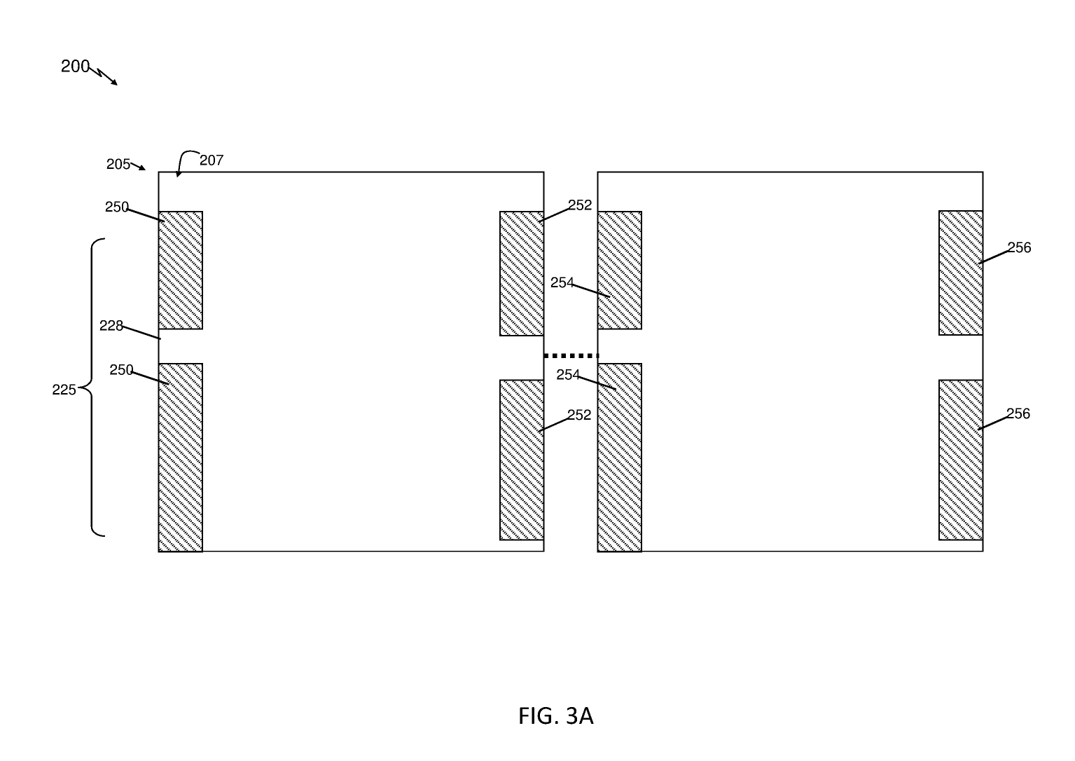

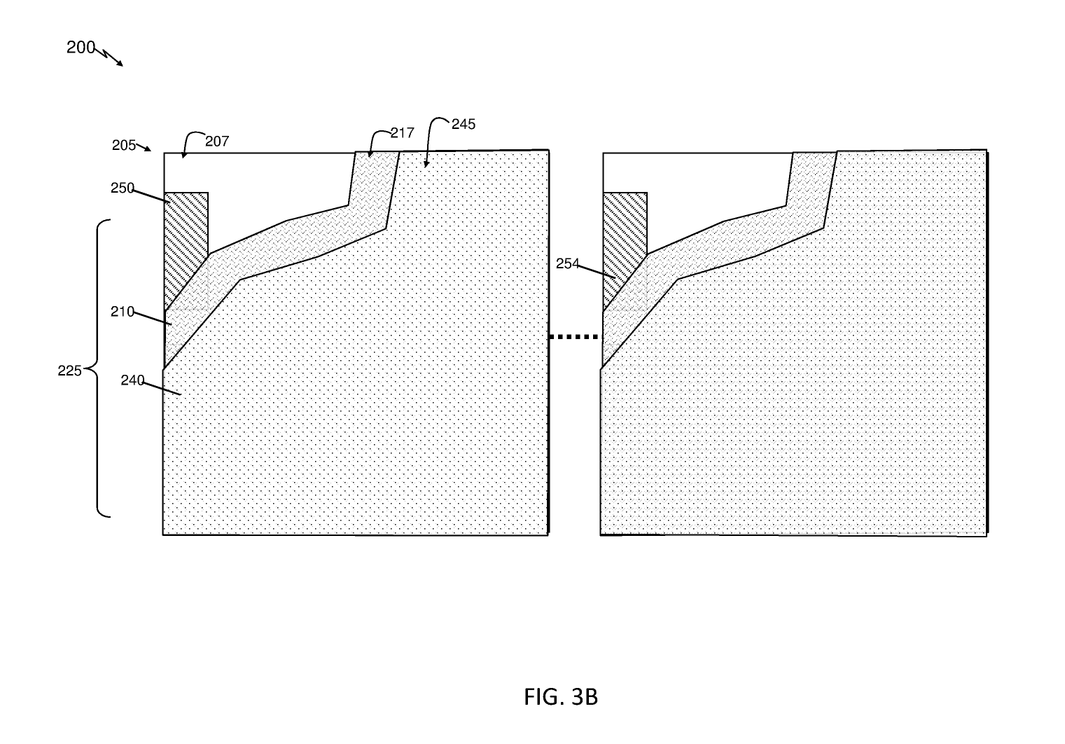

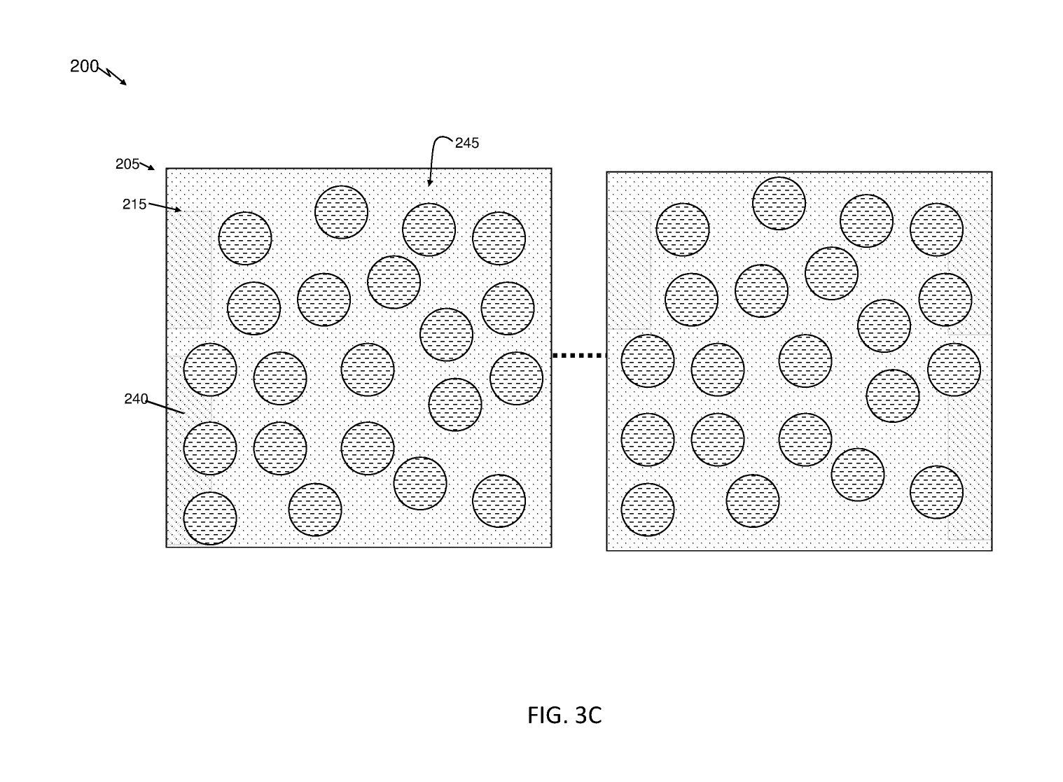

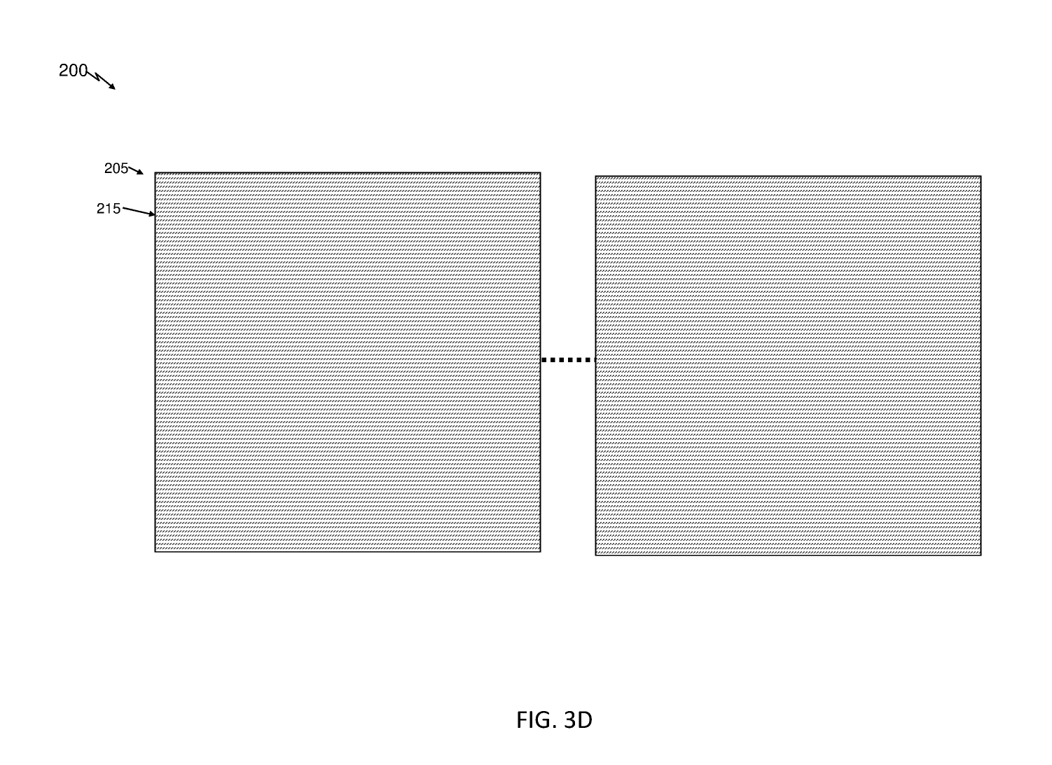

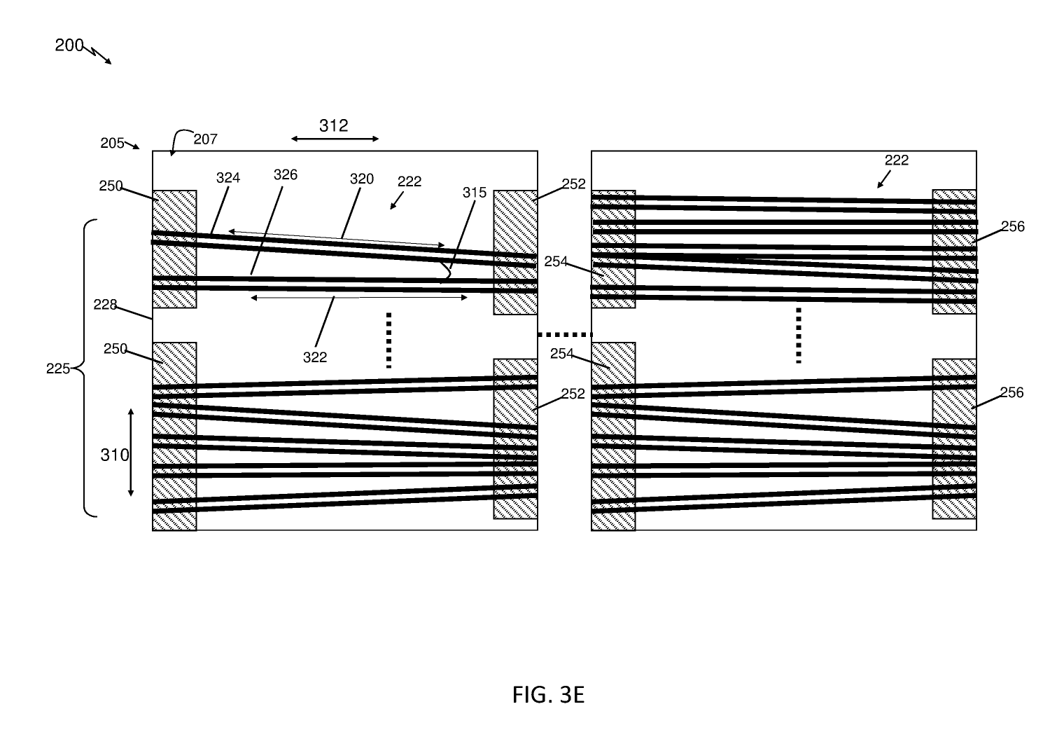

FIGS. 3A to 3E present plan views of example electrical devices at selected stages of manufacture, such as different steps in the example method disclosed in the context of FIG. 1 and corresponding to FIGS. 2A to 2E, respectively;

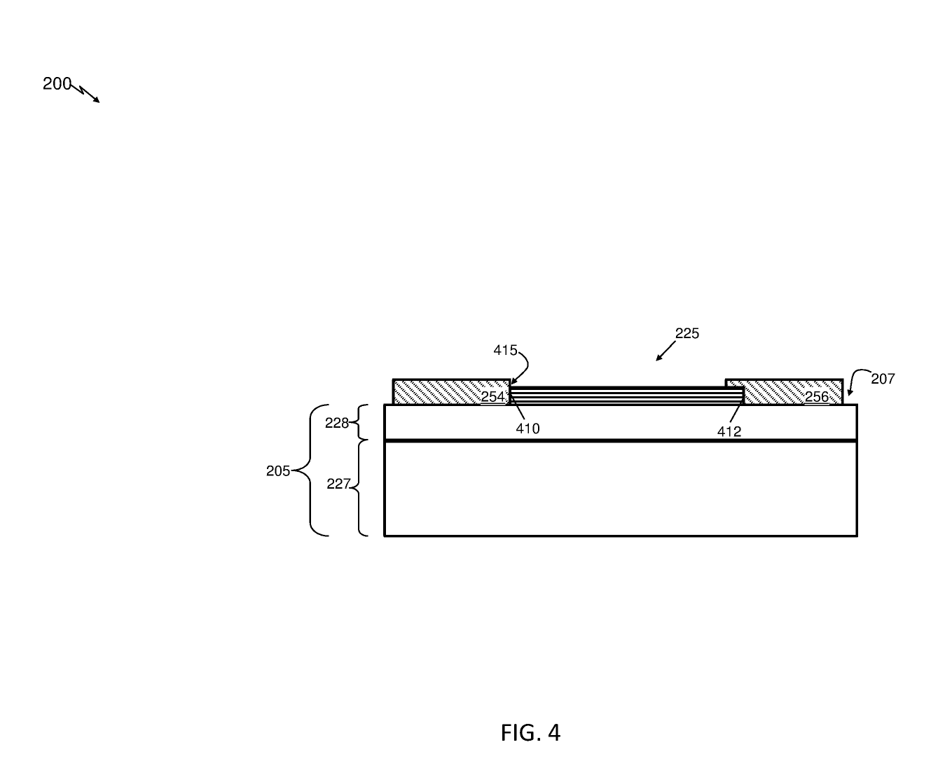

FIG. 4 presents a cross-section view of an example back-gate field effect transistor embodiment of the electrical device;

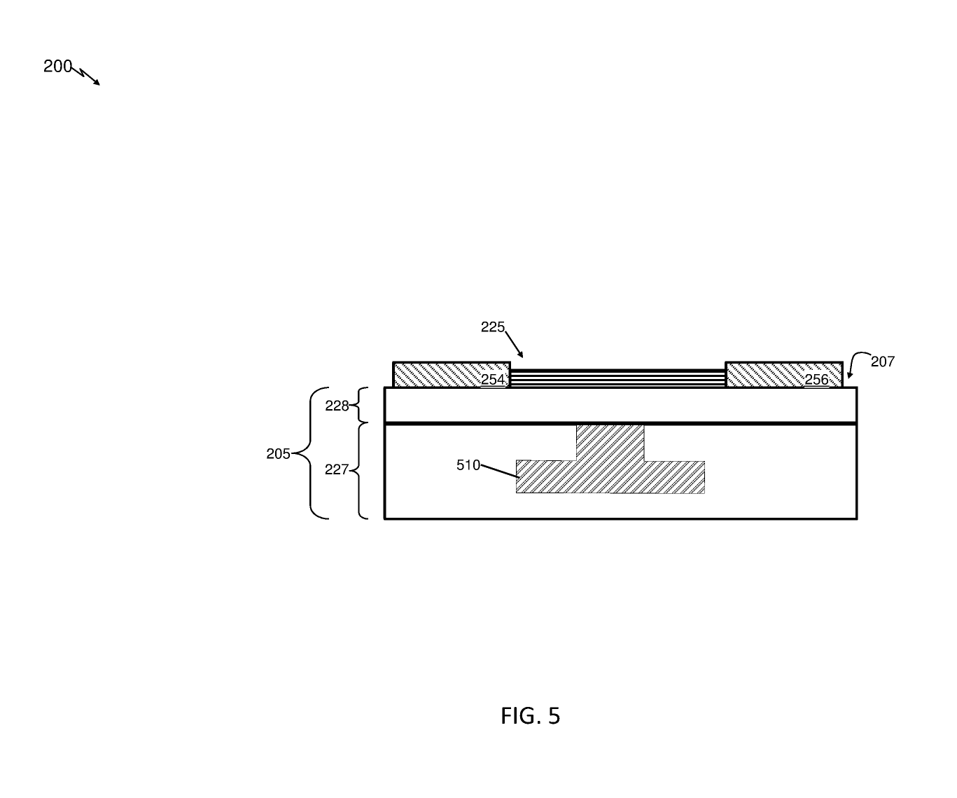

FIG. 5 presents a cross-section view of an example T-gate field effect transistor embodiment of the electrical device;

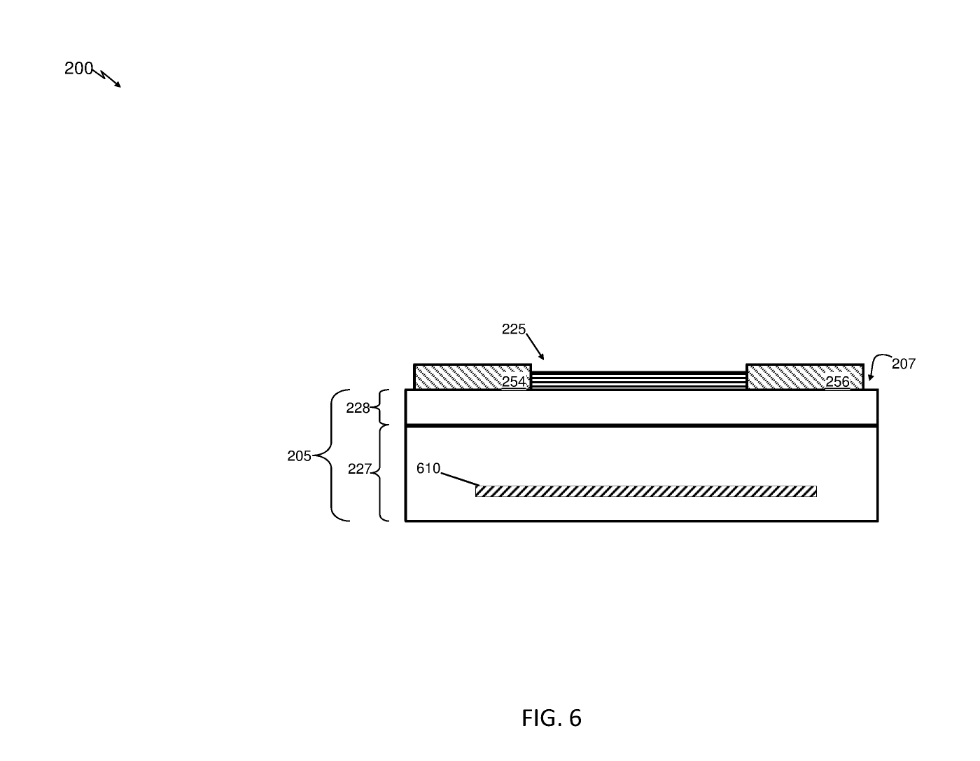

FIG. 6 presents a cross-section view of an example metal-gate field effect transistor embodiment of the electrical device;

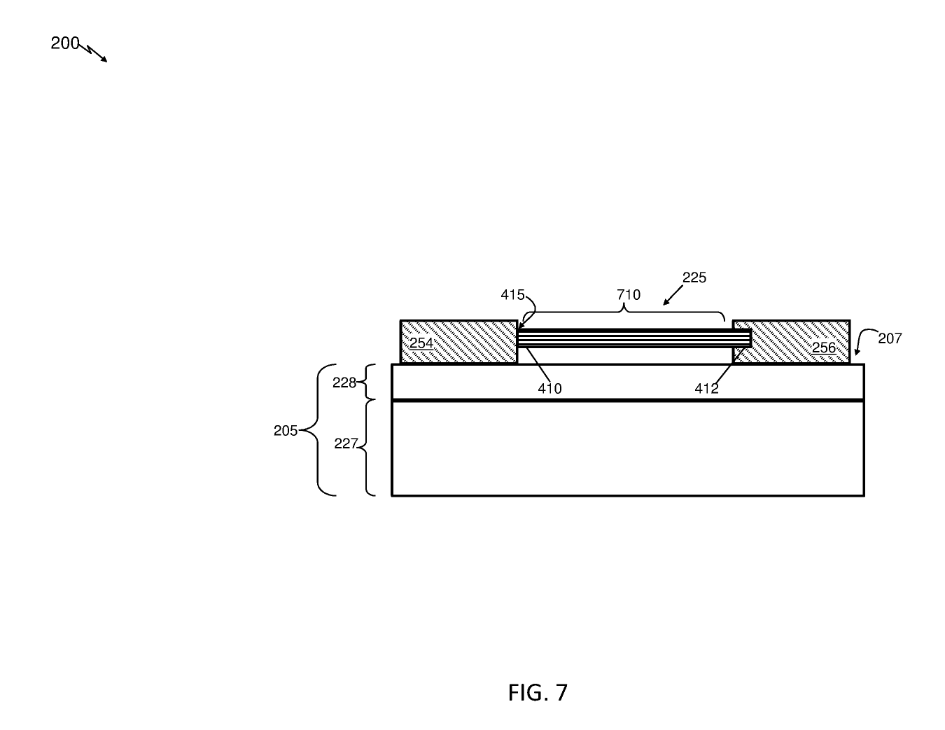

FIG. 7 presents a cross-section view of an example CNT-suspended field effect transistor embodiment of the electrical device; and

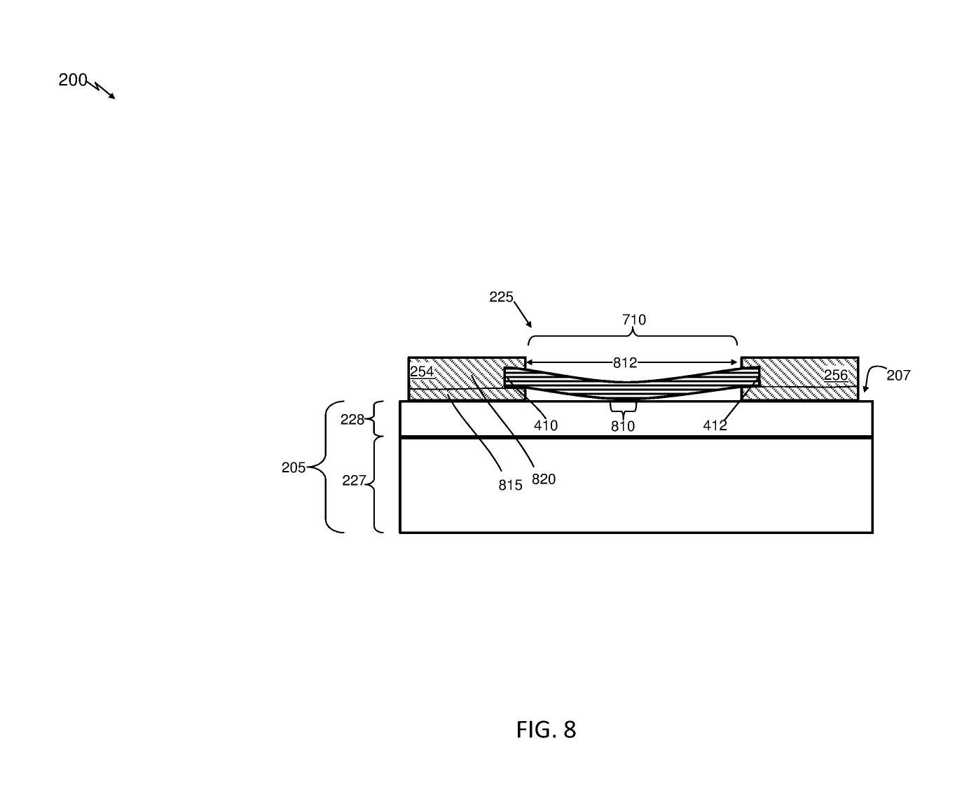

FIG. 8 presents a cross-section view of another example CNT-suspended field effect transistor embodiment of the electrical device.

### DETAILED DESCRIPTION

Embodiments of the present disclosure benefit from our discovery of a process that enables the deposition of aligned CNTs onto the surface a broad range of substrate materials and/or on non-uniform substrate surfaces that are typically not considered compatible with conventional FESA deposition processes.

We have discovered that CNTs can be deposited on a sacrificial layer that is conducive to the formation of aligned nanotubes and then the sacrificial layer can be removed to leave the aligned CNTs intact on the underlying substrate. It was surprising and non-obvious that procedures to remove the underlying sacrificial layer and the removal of the structural support of the sacrificial layer itself did not negatively affect the CNTs or their self-alignment. It was surprising and non-obvious that the deposition process disclosed herein could be applied to an arbitrary substrate that has a uniform or non-uniform surface and can be composed of a broad range of arbitrary or different materials and have heterogeneous material compositions. These features open the opportunity to place aligned CNTs into a variety of stages of semiconductor device manufacturing processes, including various field effect transistor designs and front-end-of line (FEOL) or back-end-of-line (BEOL) process stages.

One aspect of the disclosure is a method of manufacturing an electrical device. FIG. 1 presents a flow diagram of an example method 100 of manufacturing an electrical device in accordance with the disclosure. FIGS. 2A to 2E present cross-sectional views of an example electrical device 200 at different stages of manufacture, such as different steps in the example method 100 disclosed in the context of FIG. 1. FIG. 3A to 3E presents plan views of example electrical devices 200 at selected stages of manufacture, such as different steps in the example method disclosed in the context of FIG. 1 and corresponding to FIGS. 2A to 2E, respectively.

With continuing reference to FIGS. 1 to 3E throughout, the embodiments of the method 100 can include providing a substrate having a surface (e.g., step 105; FIGS. 2A and 3A, substrate 205, substrate surface 207). Embodiments of the method 100 can include providing a sacrificial layer, where the sacrificial layer is on the surface of the substrate (e.g., step 110; FIGS. 2B and 3B, sacrificial layer 210; in FIG. 3B portions of the sacrificial layer 210 are not shown so that certain underlying features can be depicted). Embodiments of the method 100 can include depositing a solution of CNTs suspended in a solvent on the surface of the sacrificial layer (e.g., step 115; FIG. 2C, CNT solution 215, surface 217). Embodiments of the method 100 can include removing the solvent of the solution to thereby leave the carbon nanotube on the sacrificial layer (e.g., step 120, FIG. 2D, solvent 220, CNTs 222). Embodiments of the method 100 can include removing the sacrificial layer (e.g., step 125) where the CNTs form a CNT layer on the substrate surface (e.g., FIGS. 2E and 3E, CNT layer 225) where the CNTs in the layer are aligned with each other.

In some embodiments of the method 100, steps 105 through 125 are conducted in the sequence disclose above and depicted in FIGS. 2A-2E and 3A-3E, while in other embodiments of the method 100 the sequence of some of these steps can be reordered.

For instance, in some embodiments, providing the sacrificial layer in step 110 can include forming the sacrificial layer on the surface of the substrate. In some embodiments, the sacrificial layer can be provided in step 110 and then the substrate can be formed on the sacrificial layer, where the sacrificial layer is on the surface of the substrate. In some embodiments, the solvent of the CNT solution can be removed in step 120 and then the sacrificial layer can be removed in step 125. In some embodiments, the sacrificial layer can be removed in step 125 while the solvent of the CNT solution is still present, and then the solvent of the CNT solution can be removed in step 120 or as part of the step 125 to remove the sacrificial layer.

Embodiments of the substrate can have an arbitrary composition. Non-limiting examples of the substrate include: one or more layers each composed of different materials such as, but not limited to, dielectric materials such as silicon oxide (e.g., SiOₓ, where x equals from about 1.5 to 2.5 or about 2.0 in some embodiment), silicon nitride, Al₂O₃, HfO₂, TiO₂, ZrO₂, AlN, diamond, spin-on-glass, benzocyclobutene; semiconductor materials such as Si, Ge, GaN, SiC, GaAs, InP; plastics or polymers; or metal materials such as copper, aluminum, gold, silver, palladium, platinum, titanium, nickel or alloys thereof. For example, some embodiments of the substrate can include a base layer (e.g., a silicon layer) and a thin film layer (e.g., a thickness of 10 microns or less) on the base layer where the thin film layer is composed a different material than the base layer or the sacrificial layer (e.g., FIG. 2A, base layer 227 and a thin film layer 228) such as, but not limited to, any of the example materials present herein. In some embodiments the substrate can be substantially free of silicon oxide, e.g., not more than about 1 weight percent or 0.1 weight percent or 0.01 weight percent of the substrate composed of silicon oxide. In some embodiments, the substrate surface of the device can be substantially free of silicon oxide, e.g., not more than about 1 percent or 0.1 percent or 0.01 percent of the total surface area of the substrate surface having silicon oxide

In some embodiments, providing the sacrificial layer (e.g., step 110) can include forming the sacrificial layer on the surface of the substrate by plasma enhanced chemical vapor deposition (PECVD), atomic layer deposition (ALD), low pressure chemical vapor deposition (LPCVD), thermal evaporation, electron beam evaporation, sputtering or other processes familiar to those skilled in the pertinent arts.

For example in some embodiments, forming the sacrificial layer on the substrate can include depositing a thin sacrificial layer (e.g., FIG. 2C, a sacrificial layer thickness 230 ranging from about 2 nm to 1000 nm or about 10 nm to 50 nm, in some embodiments and not more than 50 nm or not more than 100 nm or not more than 200 nm in some embodiments) via PECVD or other deposition procedures familiar to one skilled in the pertinent art. In some such embodiments, the choice of film thickness of the sacrificial layer can be a balance between having a film thickness sufficient (e.g., at least 2 nm or at least about 10 nm in some embodiments) to cover the substrate surface continuously such that there are no gaps, or islands, etc. on the substrate surface, versus having a thickness so large (e.g., a thickness 230 of 50 nm or greater, or 100 nm or greater, or 200 nm or greater, in some embodiments) such that the subsequent etching of the sacrificial layer takes an undesirably long times (e.g., several hours), during which time degradation of the CNTs or changes in CNT alignment or adhesion may occur.

In some embodiments, the sacrificial layer can include, or be composed of, a silicon oxide layer such as a silicon dioxide layer (e.g., at least about 90 and in some embodiments 99 percent of the sacrificial layers including or consisting of silicon oxide such as silicon dioxide in some embodiments). Having the sacrificial layer composed of silicon oxide can advantageously facilitate the formation of self-aligned CNTs thereon. Moreover, silicon oxide deposition is compatible with various tools (e.g., PECVD deposition tools) widely available in the semiconductor industry that are capable of applying uniform thin films of silicon oxide on a variety of substrate surfaces. Additionally, there are a variety of silicon oxide etch processes (e.g., acid etch processes such a HF vapor etch) that are compatible with semiconductor fabrication processes and applicable to the step of removing the sacrificial layer, e.g., as part of step 125.

Non-limiting examples of other materials of the sacrificial layers include silicon nitride, Al₂O₃, HfO₂, TiO₂, ZrO₂, AlN.

In some embodiments, the surface of the sacrificial layer is such that the solution of CNTs can form a contact angle on the surface of the sacrificial layer that is in a range of about 5 to about 90 degrees, and in some embodiments, about 5 to about 30 degrees, and in some embodiments, about 30 to 60 degrees, and in some embodiments, about 60 to 90 degrees. For instance as illustrated in FIG. 2C, individual droplets of the CNT solution 215 deposited in the sacrificial layer surface 217 can form a contact angle 235 in these ranges.

For certain deposition procedures (e.g., FESA procedures), if the contact angle is too high (e.g., greater than 90 degree, or greater than 80 degrees, or greater than 70 degrees in some embodiments) then the CNT solution may poorly wet or non-uniformly wet the sacrificial layer surface, resulting in the total area of the sacrificial layer surface not being touched by the CNT solution. This, in turn, may result in lower than desired self-alignment of the CNTs following step 120 or step 125.

For certain deposition procedures, if the contact angle is too low (e.g., less than 1 degree, or less than 5 degrees, or less than 15 degrees, in some embodiments) then the CNT solution may spread rapidly on the sacrificial layer surface in an uncontrolled manner, which in turn may result in lower than desired self-alignment of the CNTs or density of CNTs on the substrate surface, e.g., following step 125.

However, for certain other deposition procedures (e.g., immersion-incubation procedures), the solution of CNTs can form such higher or lower contact angles on the sacrificial layer surface without detrimentally affecting the alignment of the CNTs.

Non-limiting examples of CNTs that can be included in the CNT solution and CNT layer include single-walled CNTs, including double-walled CNTs and in some embodiments, substantially (e.g., at least about 90 percent or at least about percent in some embodiments) semiconducting single-walled CNTs. In some embodiments, the single-walled carbon nanotube can be wrapped in a polymer. Non-limiting example polymers include polyfluorene derivatives disclosed by Arnold, et al. (U.S. Pat. No. 9,425,405, incorporated by reference herein in its entirety). In some embodiments, the density of the CNTs in the CNT solution can range from 1 microgram CNTs per milliliter of the solution to 25 microgram CNTs per milliliter of the solution.

Non-limiting examples of the solvent of the CNT solution includes chloroform or chloroform plus one or more alcohols (e.g., methanol, ethanol, propanol) or other alcohols or organic liquids in quantities that are miscible with chloroform).

Non-limiting examples of depositing the solution of the CNTs (step 115) include immersion-incubation procedures, spin casting procedures, FESA procedures, transfer printing, dip coating procedures or other procedures familiar to those skilled in the pertinent arts.

For example in some embodiments, depositing the solution of CNTs by the immersion-incubation procedure can include immersing the substrate, with the sacrificial layer thereon, in the solution of CNTs, incubating the substrate and the sacrificial layer, in the CNT solution at a temperature in a range from about 2 to 60° C. for a period in a range from about 5 to 500 minutes for the CNTs to adhere to the sacrificial layer surface, and then removing the substrate from the solution.

For example in some embodiments, depositing the solution of CNTs onto the sacrificial layer by the FESA procedure can include: 1) dipping the substrate with the sacrificial layer thereon into a subphase of liquid (e.g., water), 2) applying the CNT solution onto the surface of the liquid subphase (e.g., as discrete drops or a continuous spray) such that the CNT solution spreads to form a planar liquid subphase-CNT solution interface, 3) allowing the spreading CNT solution to contact the sacrificial layer thereby forming a liquid subphase-CNT solution-sacrificial layer interface, 4) translating the liquid subphase-CNT solution-sacrificial layer interface across a portion or the entire substrate surface.

The CNT solution can be applied onto the subphase either continuously, (e.g., as a spray), or discretely, (e.g., as drops) throughout the time that the liquid subphase-CNT solution-sacrificial layer interface is being translated. The liquid subphase-CNT solution-sacrificial layer interface can be translated over a linear distance to coat all or a portion of an area of the substrate with the CNT layer, such that the area is defined by the length of the liquid subphase-CNT solution-sacrificial layer interface in one dimension and the linear translation distance in the other dimension.

In some embodiments, the translation rate of the liquid subphase-CNT solution-sacrificial layer interface can be a rate in a range from 1 millimeter per minute to 25 millimeter per minute. In some embodiments, the thickness of the planar CNT solution layer on the liquid subphase can range from 10 microns to 500 microns. In some embodiments, the rate that the CNT solution is introduced to the liquid subphase can range from 50 microliters per minute to 1000 microliters per minute.

Non-limiting examples of removing the solvent from the CNT solution (step 120) include: evaporation of the solvent into the ambient environment; solvent spreading away from the substrate onto a spatially separated area of a subphase; drying with forced air (e.g., nitrogen, air or similar gases); rinsing the CNT solution with a suitable pure solvent (e.g., without dissolved CNTs present therein) and subsequent drying; spin-drying (e.g., centrifugal force by spinning the substrate); elevating the substrate such that the solvent loses contact with the substrate due to gravity; suctioning the solvent from the substrate surface; wicking the solvent with a capillary or combinations of such procedures.

As illustrated in FIG. 1, in some embodiments to facilitate forming the desired wetting and spreading of the CNT solution on the sacrificial layer and over the substrate surface, the method 100 can further include the optional step 130 of depositing a hydrophobic agent on the surface of the sacrificial layer to form a hydrophobic layer on the sacrificial layer (e.g., FIGS. 2B-2D, hydrophobic layer 240; in FIG. 3B portions of the hydrophobic layer 240 are not shown so that certain underlying features can be depicted).

In such embodiments of the method 100, depositing the CNT solution (step 115) further includes depositing the solution on the surface of the optional hydrophobic layer (e.g., surface 245). In some embodiments the deposited CNT solution forms the contact angle on the surface of the hydrophobic layer similar to the contact angle disclosed above for embodiments with no hydrophobic layer present (e.g., a range of about 5 to about 90 degrees, and in some embodiments, about 5 to about 30 degrees, and in some embodiments, about 30 to 60 degrees, and in some embodiments, about 60 to 90 degrees). In such embodiments removing the solvent from the CNT solution (step 120) can include thereby leaving the CNTs on the hydrophobic layer. In such embodiments removing the sacrificial layer (step 125) can includes also removing the hydrophobic layer.

Non-limiting example embodiments of the hydrophobic agent includes hexamethyldisilazane, thiols, silanes or other organosilicon molecules known to produce a hydrophobic layer to facilitate forming the desired contact angle range of the solution on the surface of the hydrophobic layer.

Embodiments of depositing the hydrophobic agent on the surface of the sacrificial layer can include vapor deposition, spin-casting, incubation in liquid solution, electrodeposition, Langmuir-Blodgett and Langmuir-Schaefer deposition or other procedures familiar to those skilled in the pertinent arts.

For example in some embodiments, depositing the hydrophobic agent by vapor deposition and incubation can include: 1) placing the substrate into a chamber that is evacuated to a pressure of less than 1 atm 2) heating the substrate to a temperature between 30 and 200° C., 3) introducing a vapor of the hydrophobic agent (e.g., hexamethyldisilazane, thiol, or silane vapor) into the chamber, 4) incubating the vapor of the hydrophobic agent and substrate for a period sufficient to allow reaction with the substrate to form a hydrophobic layer.

Some embodiments of the method can further include pretreating the surface of the substrate prior to forming the sacrificial layer on the substrate surface (e.g. step 140). Some embodiments of the method can further include pretreating the surface of the sacrificial layer prior to depositing the hydrophobic layer on the sacrificial layer surface (e.g. step 145). Non limiting examples of pretreatments (e.g., steps 140 or 145) include: aqueous cleaning (including acidic or basic cleaning, e.g. piranha or RCA cleaning), UV-ozone cleaning, plasma cleaning, or solvent cleaning.

Non-limiting examples of removing the sacrificial layer and optional hydrophobic layer (e.g., step 125) include etching the sacrificial layer and optional hydrophobic layer via reactive ion etching, wet etching, vapor etching (e.g., HF vapor etching), ion milling, or other procedures well known to those skilled in the pertinent arts, such that the CNTs descend onto and adhere to the substrate surface. As part of step 125, removing the sacrificial layer and optional hydrophobic layer can occur while the CNTs are adhered to the remaining sacrificial layer surface and/or the optional hydrophobic layer surface.

A non-limiting example of vapor etching as part of step 125 includes: 1) placing the substrate into a chamber, 2) adjusting the temperature of the substrate to a temperature in a range from 10° C. to 100° C., 3) introducing a vapor etchant (e.g., HF vapor) into the chamber to expose the surface of the sacrificial layer and/or the surface of the optional hydrophobic layer to the vapor etchant, 4) allowing the vapor etchant to etch the sacrificial layer and optional hydrophobic layer for a controlled time, 5) removing the substrate from the presence of the vapor etchant after the sacrificial layer and optional hydrophobic layer have been removed.

In some embodiments, the vapor etchant can include HF vapor supplied from anhydrous hydrogen fluoride. In some embodiments, the wet etchant can include an aqueous hydrofluoric acid solution (e.g., 1 vol % to 50 vol % HF in water), a solution of HF in alcohol solvents, hydrofluoric acid in an aqueous and alcohol mixture, or other organic solvents familiar to those skilled in the pertinent art. In some embodiments, as part of step 125, additional or alternative etches (e.g., non-vapor etches) can be used to facilitate removing the sacrificial layer (e.g., a non-silicon oxides sacrificial layer) or optional hydrophobic layer.

In some embodiments, the CNTs of the CNT layer formed on the substrate surface can have a packing density of at least about 40 CNTs/μm, and in some embodiments at least about 100 CNTs/μm, and in some embodiments at least about 300 CNTs/μm) in a dimension (e.g., FIG. 3E, lateral dimension 310) that is perpendicular to the long axis length (e.g., perpendicular to an average long axis length dimension 312 of the CNTS).

As noted, after removing the sacrificial layer and optional hydrophobic layer (step 125) the CNTs are aligned with each other. The term aligned with each other, as used herein, is defined as the long axis of the individual carbon nanotube being co-linear with each other (e.g., in a target common direction) such that an alignment angle between CNTs is within about ±20 degrees (average±SD) for adjacent ones of the CNTs. For example as illustrated in FIG. 3E, an angle 315 between the average long axis length dimensions, 320, 322 of individual adjacent tubes 324 and 326, respectively, is within about ±20 degrees. In some embodiments, the alignment angle can be within about ±10 degrees or within about ±5 degrees, with consequent increased electrical conductivity of the CNT layer. In some embodiments, an average angle between the individual tubes and the target preferred alignment direction (e.g., a direction parallel to long axis dimension 312 for the device embodiment depicted in FIG. 3E) can be within about ±20 degrees or within about ±10 degrees or within about ±5 degrees.

In some embodiments, after removing the sacrificial layer and optional hydrophobic layer (step 125) at least a portion of the CNTs of the layer of CNTs can directly touch the surface of the substrate. The term at least a portion touching the surface of the substrate, as used herein, is defined as at least about 50 percent (e.g., at least about 75 percent, at least about 90 percent, at least about 99 percent in some embodiments) of the CNT's length (e.g., FIG. 3E the CNTs along long axis dimension 312) on the substrate directly touching the surface of the substrate. For example as illustrated in FIG. 2E, in some embodiments about 100 percent of the CNT layer 225 can directly touch the substrate surface which, e.g. can include electrical contacts 250, 252 that are co-planar with the bulk of the substrate surface 207.

In other embodiments, after removing the sacrificial layer (step 125) the CNTs of the layer of CNTs substantially do not contact the surface of the substrate. The term substantially not touching the surface of the substrate, as used herein is defined as not more than about 10 percent (e.g., not more than about 25 percent, not more than about 50 percent, in some embodiments) of the CNT's length on the substrate does not directly physically contact the surface of the substrate.

For example as further illustrated in FIG. 2E, in some embodiments a portion of the CNT layer 225 can lay on or at least touch electrical contacts 254, 256 that are elevated above the bulk of the substrate surface and thus the CNT layer substantially does not touch the other portions of the surface of the substrate (e.g., not touching the surface 258 of layer 228).

In some embodiments, the choice of the desired amount of contact between the CNT layer and the substrate surface can be a balance between several variables that are newly recognized as part of the present disclosure. In some embodiments, having the CNT layer substantially not touching the surface of the bulk of the substrate can minimize substrate-CNT layer interactions which could otherwise negatively affect the electronic or optical properties of the CNT layer (e.g. reduce electron mobility due to scattering of electrons by phonons in the substrate). Having the CNT layer substantially not touching the surface of the bulk of the substrate can advantageously facilitate forming a dielectric material entirely around the portion of the CNT layer that does not touch the substrate surface (e.g., the formation of a wrap-around gate dielectric layer). These advantages may be balanced with having the CNT layer substantially not touching the surface of the substrate resulting in a detrimental reduction in the amount of overlap between the CNT layer and electrical contacts, which in turn could result in increased contact resistance or increase the likelihood of failed contacts. Having at least a portion of the CNTs of the layer of CNTs directly touching the other portions of the surface of the bulk of the substrate (e.g., thin layer 228) can improve the adhesion of the CNT layer to the substrate surface thereby decreasing the likelihood of de-adhesion of the CNT layer during subsequent device processing steps, and/or, increase FET gate modulation. On the other hand having at least a portion of the CNTs of the layer of CNTs directly touching the surface of the substrate can increase deleterious substrate-CNT layer interactions, e.g., substrate phonons scatter CNT charge carriers leading to reduced electron mobility.

In some embodiments, the substrate surface is a substantially planar surface e.g., a surface roughness of not more than ±5 nm. In other embodiments the substrate surface can have a non-planar surface (e.g., a surface roughness of greater than ±5 nm) including surface topographies including device components that are raised above the bulk of the surface of the substrate. For instance embodiments of the substrate can have electrode contacts (e.g., FIG. 2E, contacts 254, 256) cantilever components or other device components that have a top surface (e.g., top surface 260) that is elevated above the plane of the bulk of the substrate (e.g., surface 258). Portions of the CNTs of the CNT layer 225 can be suspended between two or more of the raised device components. Portions of the CNTs of the CNT layer 225 can be adhered to the one or more of the raised device components.

In some embodiments, the substrate surface can consist of a single material (e.g., thin layer 228 or base layer 227). For instance, at least about 90, or at least about 99 percent of the surface is composed of a single material.

In other embodiments the substrate surface can consist of two or more materials having different material compositions than each other (e.g., a dielectric material thin layer 228 and metal contact layers 250, 252, 254, 256). For instance, at least about 1 percent of the surface is composed of each of the two or more different materials. Non-limiting examples include surfaces having both one or more metal layers and one or more dielectric layer, one or more first dielectric layers and one or more second dielectric layers (where the first and second dielectric layers have different material compositions), one or more first metal layers and one or more second metal layers (where the first and second metal layers have different material compositions), one or more plastic layers and one or more dielectric layers, or one or more plastic layers and one or more metal layers.

Another aspect of the disclosure is an electrical device, such as any of the devices disclosed herein as disclosed in the context of FIGS. 1-3E. For instance, with continuing reference to FIGS. 2A-3E, embodiments of the device 200 can include a substrate 205 having a surface 207 and a layer of CNT 225 on the surface of the substrate where the CNTs (e.g., CNTs 324, 326) in the layer are aligned with each other.

In some embodiments, the substrate surface can be substantially free of silicon oxide (e.g., the total area of the substrate surface is covered by less than 5 percent or less than 1 percent or less than 0.1 percent of a silicon oxide sacrificial layer).

Alternatively or additionally, in some embodiments, the substrate surface can be substantially free of a hydrophobic layer (e.g., the total area of the substrate surface is covered by less than 5 percent or less than 1 percent or less than 0.1 percent of a hydrophobic layer)

Alternatively or additionally, in some embodiments, at least a portion of the substrate surface can have a surface roughness of greater than ±5 nm (e.g., due to the presence of raised device components 254, 256).

Alternatively or additionally, in some embodiments, the substrate surface that the CNTs in the layer lay on can include at least two different material layers.

Alternatively or additionally, in some embodiments, at least a portion of the carbon nanotubes of the layer can directly touch the surface of the non-silicon oxide substrate.

Embodiments of the CNT layer can be incorporated into a wide range of electrical device configurations.

For instance, FIG. 4 presents a cross-section view of an example back-gate field effect transistor (FET) embodiment of the electrical device 200. The FET device can include source and drain electrodes 254, 256 located on the surface 207 of the substrate 205 and an electrically conductive CNT layer 225, wherein one end (e.g., one of end 410 or 412) of the CNT layer 225 contacts, and in some embodiments is adhered to, the source electrode (e.g., one of electrodes 254 or 256) and a opposite end (e.g., the other of end 410 or 412) of the CNT layer contacts, and in some embodiments is adhered to, the drain electrode (e.g., the other of electrodes 254 or 256).

As illustrated, the CNT layer 225 can directly contact the substrate surface 207. In some embodiments the substrate can include a thin film layer 228, e.g., located on a base layer 227. The thin film layer 228 can be substantially silicon oxide free and composed of a material to provide higher dielectric constant, lower contact resistance, reduced device hysteresis, higher charge carrier mobility, and or higher stability at high temperatures as compared to a silicon oxide layer.

For instance, FIG. 5 presents a cross-section view of another example T-gate field effect transistor embodiment of the electrical device. Embodiments of the device 200 presented in FIG. 5 can have all of the features of the device presented in FIG. 4 and further include a T-gate electrode 510 (e.g., a metal T-gate electrode) buried in the substrate 205, and configured to generate an electric field capable of altering the resistivity of the CNT layer 225, such that the CNT layer 225 serves as a channel region of the FET device 200.

For instance, FIG. 6 presents a cross-section view of another example metal-gate field effect transistor embodiment of the electrical device. Embodiments of the device 200 presented in FIG. 6 can have all of the features of the device presented in FIG. 5 with a rectangular shaped gate electrode 610 buried in the substrate 205, and configured generate an electrical field capable of altering the resistivity of the CNT layer 225, such that the CNT layer 225 serves as a channel region of the FET device 200.

For instance, FIG. 7 presents a cross-section view of another example CNT-suspended field effect transistor embodiment of the electrical device. Embodiments of the device 200 presented in FIG. 7 can have all of the features of the device presented in FIG. 4 but with the CNT layer 225 suspended above the surface 207 of the substrate (e.g., above thin layer 228 or above base layer 227) and one end (e.g., one of ends 410, 412) contacting, and in some embodiments adhered to, the source electrode (e.g., one of electrodes 254 or 256) and a opposite end (e.g., the other of ends 410, 412) of the CNT layer, and in some embodiments adhered to, the drain electrode (e.g., the other of electrodes 254 or 256), and a mid-section of the layer (e.g., section 710) suspended above the substrate surface 207. Such a configuration can be conducive to reducing undesirable interactions between the CNT layer and the substrate (e.g., layer 227 or optional layer 228) so as to provide a FET device configuration where the CNT layer has increased electron mobility and therefore there is increased electrical conductivity through the CNT layer.

For instance, FIG. 8 presents a cross-section view of another example CNT-suspended field effect transistor embodiment of the electrical device 200. As illustrated, in some embodiments of the device 100, the mid-section 710 of the CNT layer 225 can be substantially suspended above the substrate surface 207, but, a portion 810 of the middle section 710 CNT layer may sag down (e.g., due to the flexibility of some embodiments of the CNTs) and contact the substrate surface 207. For instance in some embodiments, the portion 810 contacting the substrate surface 207 is up to about 99 percent, up to about 90 percent, up to about 50 percent, up to about 25 percent or up to about 10 percent, of the total length 812 of the CNT layer located in-between the electrodes 254 or 256. Such partial direct contact with the substrate can reduce electron mobility as compared to a configuration where the middle section 710 of the CNT layer 225 is fully suspended above the surface (e.g., CNT layer 225 FIG. 7) but still provides improved electron mobility as compared to a configuration where the CNT layer 225 fully directly contacts the substrate surface 207 (e.g., CNT layer 225 FIG. 4).

As illustrated in FIG. 4 or 7, one or both of the ends of the CNT layer can contact or be adhered to sidewalls of one or both of the respective electrodes (e.g., end 410 of layer 225 contacting sidewall 415 of electrode 254). In other embodiments, one or both of the ends of the CNT layer can be embedded in the respective electrodes (e.g., end 412 of layer 225 embedded within electrode 256). Embedding one or both the ends in the electrodes can beneficially reduce the contact resistance between the CNT layer and the electrodes.

In some embodiments, to embed one or both of the ends of the CNT layer in one or both of the electrodes, the CNT layer can be formed as disclosed in the context of steps 105-125) such that the ends of the CNT layer are located on a first portion of the electrodes (e.g., FIG. 8, first electrode layer 815). First portions of the electrodes can be formed on the substrate surface as part of providing the substrate in step 105 (e.g., FIG. 1, step 150) Subsequently, a second portion of the electrodes (e.g., FIG. 8, second electrode layer 820) can be formed on the first portion of the electrode such that one of both ends of the CNT layer are embedded in the electrodes (e.g., FIG. 8, ends 410, 412 both embedded in first and second layers 815, 820 of the electrodes 254, 256, respectively). One skilled in the pertinent arts would be familiar with procedures to form the second portion of the electrodes on the first portion of the electrodes, (e.g., FIG. 1, step 155). For instance, using procedures familiar to those skilled in the pertinent arts, lithography and patterning procedures can be used to form openings of a photoresist layer covering the substrate surface and the CNT layer, the openings formed over the first portion of the electrodes, and, the electrode material can be deposited in the openings the photoresist layer to form the second portion of the electrodes on the first portion of the electrodes.

While this specification contains many implementation details, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. For example, it should be understood that terms of positioning and orientation (e.g., top, vertical) have been used to describe the relative positioning and orientation of components, but the components can be held in various positions or orientation (e.g., a vertical or horizontal orientation or some other orientation). Moreover, the separation of various system components in the embodiments described above should not be understood as requiring such separation in all embodiments.

Thus, particular embodiments of the invention have been described. Other embodiments are within the scope of the following claims. For example, the actions recited in the claims can be performed in a different order and still achieve desirable results.

Those skilled in the art to which this application relates will appreciate that other and further additions, deletions, substitutions and modifications may be made to the described embodiments.

What is claimed is:

1. A method of manufacturing an electrical device, comprising:
providing a substrate having a surface and
providing a sacrificial layer on the surface of the substrate;
depositing a solution of carbon nanotubes suspended in a solvent on a surface of the sacrificial layer;
removing the solvent of the solution to thereby leave the carbon nanotubes on the sacrificial layer; and
removing the sacrificial layer whereby the carbon nanotubes form a carbon nanotube layer and the carbon nanotubes in the carbon nanotube layer are aligned with each other.

2. The method of claim 1, wherein:
the substrate includes a base layer and a thin film layer on the base layer, the thin film layer providing the substrate surface, the substrate surface substantially free of silicon oxide, and
the sacrificial layer is composed of silicon oxide having a formula of SiOₓ, wherein x equals from about 1.5 to 2.5.

3. The method of claim 1, wherein the solution of carbon nanotubes forms a contact angle on the surface of the sacrificial layer that is in the range of about 5 to about 90 degrees.

4. The method of claim 1, wherein the carbon nanotubes are single-walled carbon nanotubes, double-walled carbon nanotubes, semiconducting single-walled carbon nanotubes, or single-walled carbon nanotubes wrapped in a polymer, and the solvent includes chloroform or chloroform plus one or more alcohols in quantities miscible with chloroform.

5. The method of claim 1, wherein depositing a solution of carbon nanotubes includes:
dipping the substrate with the sacrificial layer thereon into a subphase of liquid water;
applying the carbon nanotube solution onto the surface of the liquid subphase to form a liquid water subphase-carbon nanotube solution-sacrificial layer interface;
translating the liquid subphase-carbon nanotube solution-sacrificial layer interface across the substrate surface, the rate of translation in a range from 1 millimeter per minute to 25 millimeter per minute.

6. The method of claim 1, wherein removing the sacrificial layer includes one of etching the sacrificial layer via wet etching or vapor etching.

7. The method of claim 1, wherein removing the sacrificial layer includes vapor etching including:
placing the substrate with the sacrificial layer and the solution of carbon nanotubes thereon into a chamber;
adjusting the temperature of the substrate to a temperature in a range from 10° C. to 100° C.; and
introducing a HF vapor etchant into the chamber to expose the surface of the sacrificial layer to etch the sacrificial layer.

8. The method of claim 1, further including:
depositing a hydrophobic agent on the surface of the sacrificial layer to form a hydrophobic layer on the sacrificial layer and then,
depositing the solution of carbon nanotubes suspended in the solvent on the surface of the sacrificial layer and on a surface of the hydrophobic layer and then,
as part of removing the sacrificial layer, removing the hydrophobic layer.

9. The method of claim 8, wherein the solution of carbon nanotubes can form a contact angle on the surface of the hydrophobic layer that is in the range of about 5 to about 90 degrees.

10. The method of claim 1, wherein the carbon nanotubes of the carbon nanotube layer have a packing density of at least about 40 carbon nanotubes per micron of dimension perpendicular to long axis lengths of the aligned carbon nanotubes.

11. The method of claim 1, wherein the carbon nanotubes aligned with each other in the carbon nanotube layer have an alignment angle between adjacent ones of the carbon nanotubes is within about ±20 degrees.

12. The method of claim 1, wherein:
depositing the solution of carbon nanotubes includes depositing the solution on electrical contacts located on, and elevated above, the surface of the substrate and,
after the removing the sacrificial layer, at least a portion of the carbon nanotube layer touch the electrical contacts and not more than about 50 percent of a length of the layer of carbon nanotubes does not directly physically contact the substrate surface.

13. An electrical device, comprising:
a substrate having a surface; and
a layer of carbon nanotubes on the surface of the substrate, wherein the carbon nanotubes in the layer are aligned with each other, such that an alignment angle between adjacent ones of the carbon nanotubes is within about ±20 degrees.

14. The device of claim 13, wherein the carbon nanotubes of the carbon nanotube layer have a packing density of at least about 40 carbon nanotubes per micron of dimension perpendicular to long axis lengths of the carbon nanotubes.

15. The device of claim 13, wherein the substrate surface is substantially free of silicon oxide.

16. The device of claim 13, wherein the substrate includes a thin film layer providing the substrate surface, the thin film layer composed of: silicon nitride, Al₂O₃, HfO₂, TiO₂, ZrO₂, AlN, diamond, spin-on-glass, or benzocyclobutene polymer.

17. The device of claim 13, wherein the electrical device is configured as a back-gate field effect transistor and further includes a source electrode and a drain electrode located on the substrate surface, wherein one end of the carbon nanotube layer contacts the source electrode and an opposite end of the carbon nanotube layer contacts the drain electrode.

18. The device of claim 17, wherein the source electrode and the drain electrode are elevated above the substrate surface and the carbon nanotube layer is suspended above the substrate surface such that not more than about 50 percent of a length of the layer of carbon nanotubes does not directly physically contact the substrate surface.

19. The device of claim 17, wherein the source electrode and the drain electrode are elevated above the substrate surface and the carbon nanotube layer is suspended above the substrate surface such that none of the layer of carbon nanotubes directly physically contacts the substrate surface.

20. The device of claim 17, wherein the field effect transistor further includes a metal gate electrode buried in the substrate, the metal gate electrode configured to generate an electric field capable of altering the resistivity of the CNT layer.
